(19) United States
(12) Patent Application Publication
(10) Pub. No.: US 2026/0121362 A1
(43) Pub. Date: Apr. 30, 2026

(54) FAN BOARD WITH ELONGATED EDGE CONNECTOR

(71) Applicant: HEWLETT PACKARD ENTERPRISE DEVELOPMENT LP, Spring, TX (US)

(72) Inventors: Chih-Wei Chiang, Taoyuan City (TW); Kuan-Wei Chen, Taipei City (TW); Hsueh-Yu Chao, Taipei (TW)

(21) Appl. No.: 18/928,497

(22) Filed: Oct. 28, 2024

(51) Int. Cl. H01R 25/00; G06F 1/20; H01R 12/73; H01R 12/79; H01R 12/91; H05K 7/20

(52) U.S. Cl. CPC H01R 25/006; G06F 1/20; H01R 12/732; H01R 12/79; H01R 12/91; H05K 7/20172

(57) ABSTRACT

A system includes a chassis and a system board supported by the chassis. The system board includes a processor mounted thereto. A system board connector is coupled to the system board. The chassis further supports a fan board including a printed circuit board (PCB) and a plurality of fan receptacles, with the plurality of fan receptacles configured to mate with corresponding fan connectors on fans. An elongated edge connector is integrally formed with the PCB and electrically connected with the plurality of fan receptacles. The elongated edge connector is slidably engageable with the system board connector such that the fan connector is movable relative to the system board between a plurality of installation positions.

### BACKGROUND

In some systems, fans used to cool the system are electrically connected directly to the system board, with an electrical connector of the fan (aka “fan connector”) connected to an electrical connector of the primary system board (aka “fan receptacle”). However, in other systems, the system board may lack fan receptacles entirely, have an insufficient number of fan receptacles for the number of fans desired for the system, or have fan receptacles that are inconveniently located. In such systems, connecting the fans directly to the system board may be difficult or impossible. In such cases, a fan board may be used to connect the fans to the system board. A fan board refers to a specific type of printed circuit board (PCB) that includes fan receptacles mounted thereto to which a fan can be coupled.

### BRIEF DESCRIPTION OF THE DRAWINGS

The present disclosure can be understood from the following detailed description, either alone or together with the accompanying drawings. The drawings and related description of the figures are included to provide a further understanding of the present disclosure and are incorporated in and constitute a part of this specification.

The drawings illustrate one or more nonlimiting aspects and implementations of the present teachings and together with the description explain certain principles and operation. In the drawings:

FIG. 1 is a block diagram of a system including a fan board with an elongated edge connector.

FIG. 2 is top (plan) view of an example of a fan board with an elongated edge connector.

FIG. 3 is a detail view of the fan board of FIG. 2.

FIG. 4 is a front view of an example system board connector for use with a fan board with an elongated edge connector.

FIG. 5 is perspective view of the example system board connector of FIG. 4.

FIG. 6 is a top perspective view of the example system board connector of FIG. 4.

FIG. 7 is a perspective view of an example assembly comprising the fan board of FIG. 2 and two of the system board connectors of FIG. 4, with the fan board being in a first installation state with respect to the system board connectors.

FIG. 8 is a top view of the portion of the assembly of FIG. 7 with the fan board in a second installation state with respect to the system board connectors.

FIG. 9 is a top view of the portion of the assembly of FIG. 7 with the fan board in a third installation state with respect to the system board connectors.

FIG. 10 is an exploded perspective view of an example system including the assembly of FIG. 7 and two system boards.

FIG. 11 is a perspective view of the example system of FIG. 10 with the fan board in the first installation state with elongated edge connectors unconnected to the system board connectors.

FIG. 12 is a perspective view of the example system of FIG. 10 with the fan board in the second installation state with the elongated edge connectors being connected to the system board connectors.

FIG. 13 is a top view of the example system of FIG. 10.

FIG. 14 is a bottom view of the system of FIG. 10.

FIG. 15 is a top view of another example system having a fan board with an elongated edge connector coupled to system boards.

FIG. 16 is a bottom view of the system of FIG. 15.

FIG. 17 is a top view of another example system having a fan board with an elongated edge connector coupled to system boards.

FIG. 18 is a bottom view of the system of FIG. 17.

FIG. 19 is an example method for installing a fan board with an elongated edge connector.

### DETAILED DESCRIPTION

A manufacturer of information processing systems may offer multiple different types or versions of systems, with the different types or versions having different configurations. These configurations may include different system boards, which may have varying dimensions, particularly the length direction. As a result of variances in dimensions, the distance between a desired fan installation location and the system board may vary from one system to the next. Thus, if the system uses board-to-board connections to couple the fan board to the system board, these systems may require differently sized fan boards to allow the intervals between the fan and the system board to be covered. However, designing and producing multiple differently sized fan boards for different systems can be costly. This can be due to needing to devote additional resources to development and design, production of different manufacturing lines when different lines are needed to produce the boards, and due to needing multiple parts numbers or stock-keeping unit (SKU) numbers, which complicates both logistics and the assembly process.

An alternative to the board-to-board connections may be using a cable to connect the fan board to the system board. Because a cable is flexible and can span a range of distances, a cabled connection may allow the same fan board to be used for multiple systems, even if the system boards are differently sized and/or if the distances between the fans and system boards are different. However, using cable-connections has challenges, including cost and increased complexity. Cables can be more expensive than board-to-board connection. Moreover, adding more cables to a system (which likely already has numerous cables as part thereof) can complicate assembly and/or servicing and repair, as a greater numbers of cables make it more difficult to determine which cables should be routed to the various components. In addition, increasing the number of cables makes cable management and routing more challenging. Increasing complexity in this manner can result in increased costs, particularly with regards to labor costs, as additional labor may be needed to properly install and manage the cables. In addition, more cables can lead to an increase in the possibility of installation errors that will need to be corrected. Cables also represent additional components within the overall system, which may obstruct airflow through the system. As a result, adding cables can alter, and potentially decrease, the efficiency of the airflow through the system.

To address these challenges, the present disclosure provides systems in which the fan boards can be coupled with the system boards using a board-to-board connection that allows for variable positioning of the fan board relative to the system board. More particularly, example fan boards disclosed herein comprise one or more elongated edge connectors which slidingly engage with corresponding receptacle connectors mounted to a system board. These connectors allow the fan board to be moved within a defined range of motion relative to the system board, with the elongated edge connector remaining electrically connected to the system board connector throughout this range of motion. As a result, the fan board can be installed in multiple possible installation positions relative to the system board. This can include a position where the fan receptacles of the fan board are very close to an edge of the system board, a position where the fan receptacles of the fan board are more distant from the edge of the system board (e.g., 30 mm or more from the edge in some examples), and positions in between. As a result, the same fan board can be used with different sized system boards. For example, if a shorter system board is used, the fan board may be positioned relatively farther from the system board. By contrast, if a longer system board is used, the same fan board may be positioned relatively closer to the system board. In both arrangements, however, the elongated edge connector is able to establish a connection to the system board.

In some examples, the system board includes a receptacle with a pass-through configuration, which allows the elongated edge connector to slide through the connector. Said differently, the receptacle has an inlet opening in a front side thereof and an outlet opening in a rear side thereof, opposite the inlet opening. This allows the elongated edge connector to enter the receptacle through the inlet opening, pass through the receptacle, and protrude out the receptacle through the outlet opening. This pass-through structure can allow for a greater range of motion of the elongated edge connector relative to the system board connector.

The system board connector may comprise pins positioned in the receptacle which slidingly engage with elongated gold fingers of the elongated edge connector. As the elongated edge connector slides relative to the system board connector, the pins of the system board connector slide along the length of the gold fingers. This maintains an electrical connection between the elongated edge connector and the system board throughout the range of motion.

In some examples, the elongated edge connector may be comprised of a recessed portion and a protruding portion. The recessed portion may be disposed in a recessed area in a rear edge of the fan board, and the protruding portion may extend from the recessed area. Said differently, the elongated edge connector may be bordered on either side by a cutout, with the cutouts being part of the recessed portion. The lateral widths of the cutouts, i.e., the distance between the lateral edges of the elongated edge connector and the opposite edges of the fan board across the cutouts, may be sufficient (e.g., about 2 mm, in some systems) to allow the side walls of the system board connector to pass into the cutouts when the fan board is moved rearward. This may enable essentially the full length of the elongated edge connector to slide through the system board connector even though only part of the elongated edge connector protrudes beyond the rear edge of the fan board. In other words, the cutouts allow the range of motion of sliding contact for the elongated edge connector to be increased without increasing the distance the edge connector protrudes beyond the fan board edge. In some examples, the elongated edge connector may protrude past the edge of the system board and the cutout, while in other examples, the elongated edge connector may be entirely bordered by the cutout, i.e., may be in a recessed position with respect to the fan board.

The elongated edge connector may have a length that is sufficient to allow the fan board to be positioned in a variety of positions. In some examples, the elongated edge connector may be about 30 mm long, allowing the fan board to move within a range of up to 30 mm with respect to the system board while still maintaining electrical connection with the system board connector. In addition, the width of the elongated edge connector may be less than the length, such that the elongated edge connector is substantially columnar (elongated) in shape. This may allow the elongated edge connector to move with respect to the system board connector, as described previously, to have allow the fan board to have a variety of positions with respect to the system board.

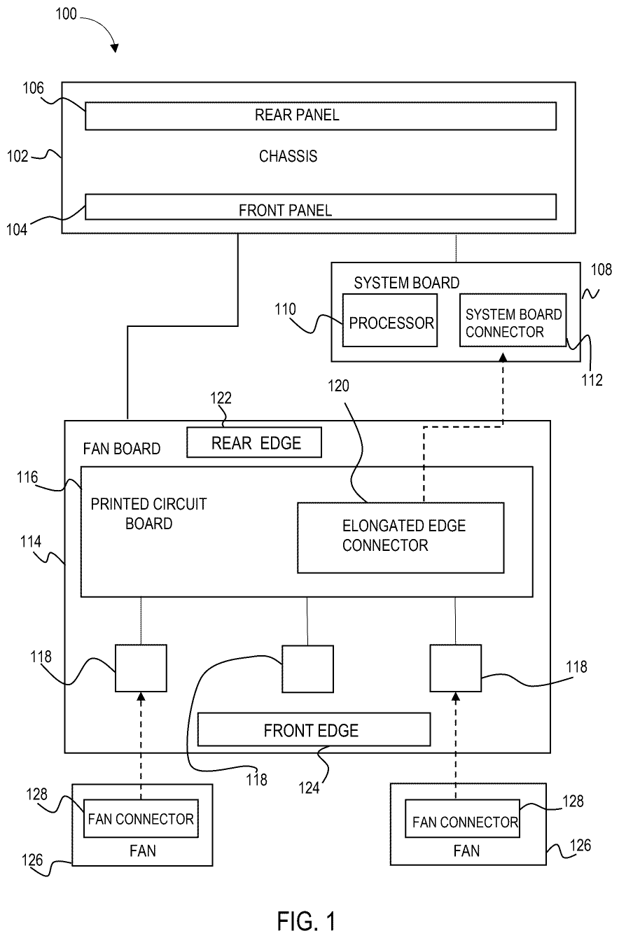

The examples mentioned above, and others, will now be described in greater detail with reference to FIGS. 1-19.

FIG. 1 is a block diagram of an example information processing system 100 including a fan board 114 having an elongated edge connector 120. It should be understood that FIG. 1 is not intended to illustrate specific shapes, dimensions, or other structural details accurately or to scale, and that implementations of the fan board 114 may have different numbers and arrangements of the illustrated components and may also include other parts that are not illustrated. In FIG. 1, physical connections (e.g. physical attachment and/or support) between components are indicated conceptually by solid lines extending between the blocks representing the components, whereas electrical connections between components are indicated conceptually by dashed lines extending between the blocks representing the components. Furthermore, connections which may be intermittent or conditional (e.g., occurring in some states but not in others) are indicated by arrows. The fan board 114 and the elongated edge connector 120 are illustrated in FIG. 1 in the context of the information processing system 100 to aid understanding, but some examples disclosed herein comprises the fan board 114 with an elongated edge connector 120 alone, (i.e., not yet installed in any information processing system), and other examples comprise an information processing system 100 with a fan board 114 having an elongated edge connector 120 installed therein.

Information processing system includes a chassis 102 which physically supports, and in some cases encloses or houses, the other components of the system. The chassis 102 may include a front panel 104 and a rear panel 106, as well as other structural members (not illustrated) such as a base, side walls, a cover, drive cages, etc.

A system board 108 may be supported by the chassis 102. The system board 108 includes a printed circuit board (PCB) (not illustrated) and various components mounted to the PCB, including at least a processor 110. The system board 108 may also include additional components mounted to the PCB, such as memory modules, power delivery components, etc., which are familiar to those of ordinary skill in the art and thus are not described in detail herein. The primary system board 108 may be a motherboard, a host processor module (HPM) board, or any other suitable board.

The system board 108 also comprises a system board connector 112, which may be coupled to the PCB of the system board 108. A system board connector refers to a connector at which a component may be connected, either selectively or permanently, with the system board. In system 100, system board connector 112 may be configured to receive an elongated edge connector 120 to couple a fan board 114 to the system board 110.

The chassis 102 may further support a fan board 114. The fan board 114 includes a printed circuit board (PCB) 116, one or more fan receptacles 118 mounted to the PCB 116, and one or more elongated edge connectors 120 formed in the PCB 116. The fan board 114 is configured to serve as a bridge between fans 126 (described below) and the system board 108, with the fan connector(s) 118 electrically connecting with the fans 126 and with the elongated edge connector(s) 120 electrically connecting with the system board 108, as will be described in greater detail below. In some examples, the fan receptacles 118 are mounted to the PCB 116 near a front edge 124 thereof, whereas the elongated edge connector 120 is formed in a rear edge 122 of the PCB 116. A fan receptacle 118 refers to an electrical connector configured to receive (e.g., physically mate with) and electrically connect with a complimentary electrical connector of a fan (e.g., fan connector 128 of fan 126 described in further detail below). The PCB 114 may communicate electrical power and/or control signals between the fans 126 and the system board 108 via the fan connectors 128 and the elongated edge connector(s) 120.

As mentioned above, an elongated edge connector 120 is formed as part of the rear edge 120 of the PCB 116. As used herein, an edge connector refers to a portion of a PCB, such as PCB 116, that comprise an edge of the PCB, is configured to mate with a complementary socket by insertion of the edge into the socket, and includes conductive traces or contact pads (also called “gold fingers”) formed adjacent the edge such that, when mated with the complementary socket, pins in the socket engage the contact pads an electrical connection is formed therebetween. As shown in FIG. 1, elongated edge connector 120 may be selectively engageable with the system board connector 112 such that, when elongated edge connector 120 engages with the system board connector 112, an electrical circuit is completed. This circuit may be used to provide power to fans 126 via the fan receptacles 118.

More particularly, each elongated edge connector 120 is configured to slidingly engage with a corresponding system board connector 112 of the system board 108. The elongated edge connector 120 is configured to connectors allow the fan board 114 to be moved within a defined range of motion relative to the system board 108, with the elongated edge connector 120 remaining electrically connected to the system board connector 112 throughout this range of motion. As a result, the fan board 114 can be installed in multiple possible installation positions relative to the system board 108. This can include a position where the fan receptacles 118 of the fan board 114 are very close to an edge of the system board 108, a position where the fan receptacles 118 of the fan board 114 are more distant from the edge of the system board 108 (e.g., 30 mm or more from the edge in some examples), and positions in between. As a result, the same fan board 114 can be used with different sized system boards 108. For example, if the system board 108 is shorter, the fan board 114 may be positioned relatively farther from the system board 108 whereas if the system board 108 is longer, the same fan board 114 may be positioned relatively closer to the system board 108. In both arrangements, however, the elongated edge connector 120 is able to establish a connection to the system board 108.

In some examples, the system board connector 112 includes a receptacle with a pass-through configuration, which allows the elongated edge connector 120 to slide through the connector 112. Said differently, the system board connector 112 has an inlet opening in a front side thereof and an outlet opening in a rear side thereof, opposite the inlet opening. This allows the elongated edge connector 120 to enter the receptacle through the inlet opening, pass through the receptacle, and protrude out the receptacle through the outlet opening. This pass-through structure can allow for a greater range of motion of the elongated edge connector 120 relative to the system board connector 112.

The system board connector 112 may comprise pins positioned in the receptacle which slidingly engage with elongated gold fingers of the elongated edge connector 120. As the elongated edge connector 120 slides relative to the system board connector 112, the pins of the system board connector 112 slide along the length of the gold fingers. This maintains an electrical connection between the elongated edge connector 120 and the system board connector 112 throughout the range of motion.

Fans 126 may be engageable with fan board 114 at fan receptacles 118. Although two fans 126 are shown in FIG. 1, examples are not so limited and other numbers of fans 126 may be used. When fans 126 are coupled to fan board 114 through the mating of fan connectors 128, formed as part of fans 126, with fan receptacles 118, located on the fan board 114, fans 126 are able to receive power from system board 108 via the fan board 114. More particularly, fans 126 receive power and thus are able to provide airflow and cooling to information processing system 100 when elongated edge connector 120 is coupled with system board connector 112.

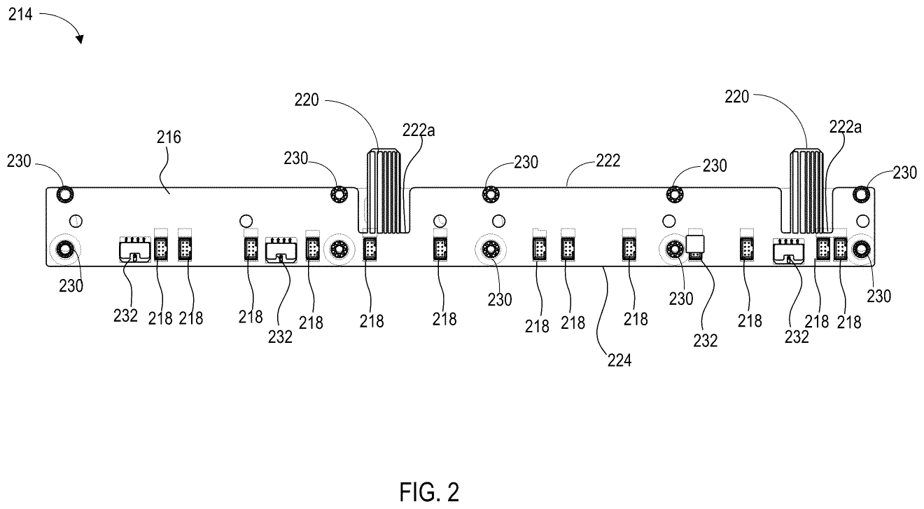

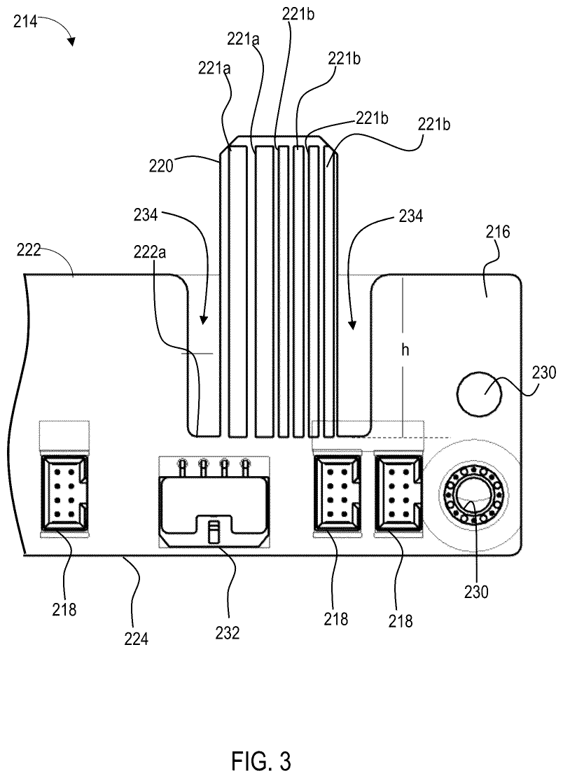

Turning now to FIGS. 2 and 3, an example of a fan board 214 with elongated edge connectors 220 is shown, with FIG. 3 being a detail view of the fan board 214 of FIG. 2. Fan board 214 may be one example implementation of fan board 114 shown in and described with respect to FIG. 1.

As can be seen in FIGS. 2 and 3, fan board 214 includes a PCB 216, fan receptacles 218 mounted to the PCB 216, and elongated edge connectors 220 formed into the PCB 216.

A plurality of mounting holes 230 formed in PCB 216 may receive connectors, such as screws, rivets, or the like to couple fan board 214 with a chassis, such as chassis 102 described with respect to FIG. 1, or to some other support structure (such as a motherboard tray) which is in turn coupled to the chassis. A rear edge 222 of the fan board 214 may be disposed opposite and parallel to a front edge 224 of the fan board 214, with elongated edge connectors 220 being formed in the rear edge 222. While two elongated edge connectors 220 are shown in FIG. 2, examples are not so limited and more or fewer elongated edge connectors may be present.

As shown in FIG. 3, elongated edge connector 220 extends rearward beyond adjoining portions of the rear edge 222 of PCB 216. More particularly, the rear edge 222 of the PCB 216 has first rear edge portions 222b, second rear edge portions 222a, and third rear edge portions 222c, all arranged at different relative positions along a front-to-rear axis. The second rear edge portions 222a are offset a distance h1 forwards from the first rear edge portions 222b. The third rear edge portions 222c are offset a distance h2 rearwards from the first rear edge portions 222b. Elongated edge connector 220 comprises one of the third rear edge portions 222c, and begins at and extends from one of the displaced rear edge portions 222a. Thus, a length of the elongated edge connector 220 may be equal to h1+h2. PCB 216 further includes cutouts 234 disposed on either side of elongated edge connector 220, with cutouts 234 extending from first rear edge portion 222b forward to displaced rear edge portion 222a. Each cutout 234 may have a width w1 sufficient to allow side walls of a complimentary system board socket to be received therein, the width w1 being measured between the longitudinally extending side-edge 223 of the elongated edge connector 220 and an opposing side-edge 225 of the PCB 216. For example, in some implementations the width w1 of the cutouts 234 is about two millimeters. In some examples, a length of the cutouts 234, which equals the distance h1, may be between ten and twenty millimeters. In some examples, h2 may be between ten and twenty millimeters. Thus, a length of the edge connector 220 may be, in some examples, between twenty and forty millimeters. Cutouts 234 allow fan board 214, and more particularly elongated edge connector 220, to have a greater range of movement when being coupled to a system board at, for example, a system board connector. More specially, although the edge connector 220 protrudes only the distance h2 from the rear edge portions 222b, the cutouts 234 allow the system connector to move the full distance h1+h2 along the length of the edge connector 220. Thus, a range of motion of the fan board 224 has a length of about h1+h2 even though the edge connector protrudes less than this distance. Said differently, when combined with the height of the elongated edge connector 220 (which may be between thirty and forty millimeters), the cutouts 234 allow fan board 214 the ability to increase an amount of movement with respect to a system board, which in turn allows the fan board 214 to be positioned at a variety of locations with respect to the system board. In some examples, the fan board 214 may be movable up to thirty millimeters with respect to the system board.

Each elongated edge connector 220 disposed on a fan board 214 has a height of h1+h2 and a width of w2, with the height being sufficiently greater than the width such that the elongated edge connector 220 is substantially columnar in shape. As noted previously, the elongated edge connector may have a height between twenty and forty millimeters, in some examples the height is between 25 and 35 millimeters, and in some examples, the height is about 30 millimeters. In addition, the elongated edge connector may have a width of between one and ten millimeters.

Each elongated edge connector 220 further comprises a plurality of contact leads 221, shown in detail in FIG. 3. More particularly, the plurality of contact leads 221 may comprise power contact leads 221a and signal communication contact leads 221b. One or more of the power contact leads 221a may receive a supply voltage (e.g., 12V) from a system board to which edge connector 220 is connected, and one or more of the power contact leads 221a may receive a ground voltage (e.g., 0V) from the system board. These power contact leads 221a are connected, via internal circuitry of the fan board 214, to power pins of the fan receptacles 218. Thus, when a fan connector is connected with a fan receptacle 218 and edge connector 220 is connected to a system board, an electrical circuit can be completed between the system board and the fan via the power contact leads 221a. Power contact leads 221a may also be connected, in some examples, to other components mounted on the fan board 214 to provide power thereto, and, in some examples, to additional connectors 232 which can allow for power to be distributed to other components of the system via cables coupled to the connectors 232. Signal communication contact leads 221b, by contrast, communicate signals between the system board and other components which are mounted or connected to the fan board 214, such as the fans (via fan connectors 218), other peripheral components via connectors 232, and any additional components that may be coupled to or formed as part of the fan board 214.

Each contact lead 221 includes conductive material which has been formed on or in a top face of the elongated edge connector 220, forming an exposed trace on the elongated edge connector 220. In some examples, the conductive material may be or include gold (solid, or plated). However, examples are not so limited, and other conductive materials such as copper, silver, etc., may be used to form the traces on contact leads 221. Historically, the contact leads of edge connectors often were gold, and thus edge connectors have become commonly known as “gold finger connectors” and the contact leads thereof as “gold fingers. ” However, over time, the terms “gold finger connector” and “gold finger” have become generic terms for the edge connectors and their contact leads regardless of whether the contact leads actually contain gold. Thus, any references herein to “gold finger” should be understood as referring to a contact lead of an edge connector but without implying any requirement that it contains gold. The conductive material on the contact leads 221 contact corresponding conductive fingers in a system board connector (described further herein) to complete the electrical connections allowing the elongated edge connector 220 to provide power to fan board 214.

In the illustrated example, the contact leads 221 each extends along substantially the full length of the elongated edge connector 220. Thus, each contact lead 221 has a length of about h1+h2. In some examples, the length of each contact lead 221 is ten times or more than a width thereof. In some examples, the length of each contact lead 221 is fifteen times or more than a width thereof.

Fan board 214 may further include a plurality of fan receptacles 218 coupled thereto. As described with respect to FIG. 2, fan receptacle 218 may be configured to receive a complementary fan connector located on a fan, such as fan connector 128 on fan 126, described with respect to FIG. 1. When a fan is coupled to a fan receptacles 218, the fan is supported by the fan board 214 and may receive power from the PCB 216 via the electrical circuit completed by the elongated edge connector 220. In addition, the fan receptacles 218 supplies communications to the fan plugged therein, such as status signals, telemetry, etc. These signals are transmitted from the signal communication leads 221b of the elongated edge connector 220, while the power is transmitted by the power contact leads 221a.

In addition, fan board 214 may include a plurality of power connectors 232. Power connectors 232 may be configured to couple with a pluggable module other than a fan, such as a front drive cage. Similar to fan receptacles 218, power connectors may receive power from the elongated edge connector 220 when the elongated edge connector 220 is coupled to a board such as a system board such that an electrical circuit is completed.

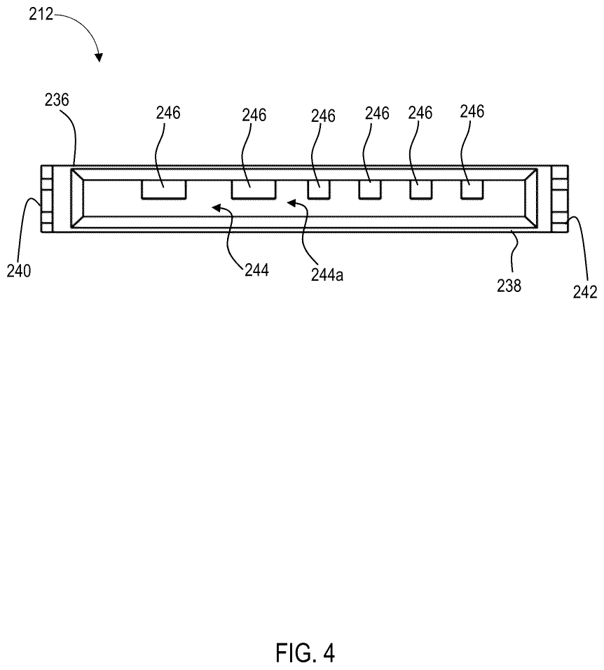

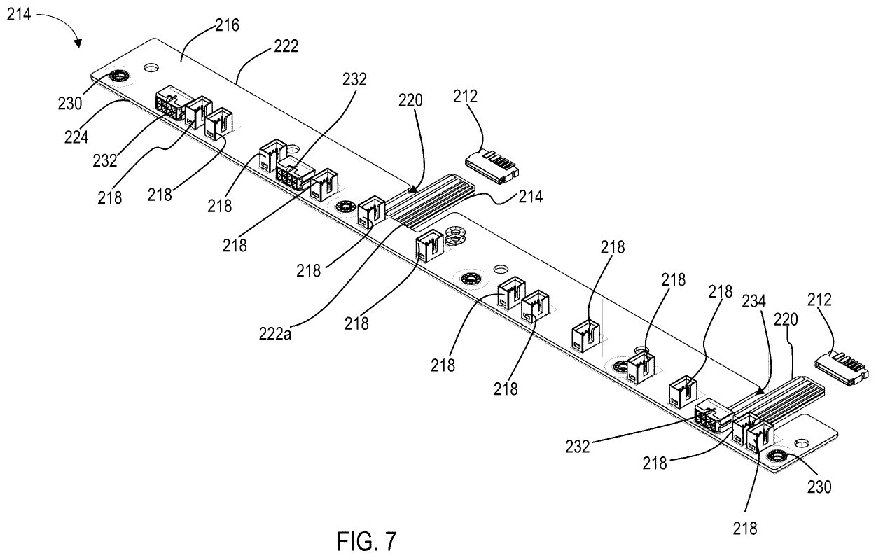

Turning now to FIGS. 4-6, an example system board connector 212 is shown. System board connector 212 may be one example implementation of system board connector 112 shown in and described with respect to FIG. 1. System board connector 212 is configured to mate with one of the elongated edge connectors 220 of the fan board 200, and thus the description of the system board connector 212 below will occasionally refer also to FIGS. 7-9, which show interactions between the system board connector 212 and the elongated edge connectors 220. System board connector 212 may be coupled to a system board, not shown in FIGS. 4-6, such that system board connector 212 is able to serve as a point of contact or connection between a separate implement (such as fan board 214) and the system board. System board connector 212 may be coupled to the system board via soldering, welding, or any other suitable attachment mechanism. Alternately, system board connector 212 may be integrally formed with the system board.

System board connector 212 includes a top wall 236 and a bottom wall 238 disposed opposite and parallel to the top wall 236. Side walls 240 and 242 extend between and connect top wall 236 and bottom wall 238.

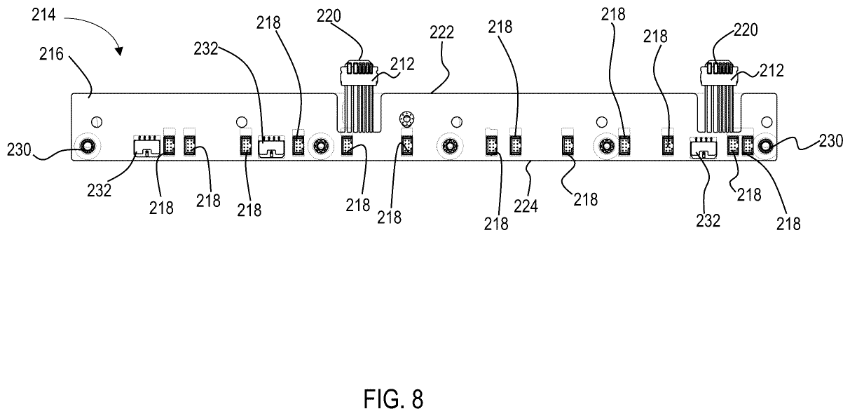

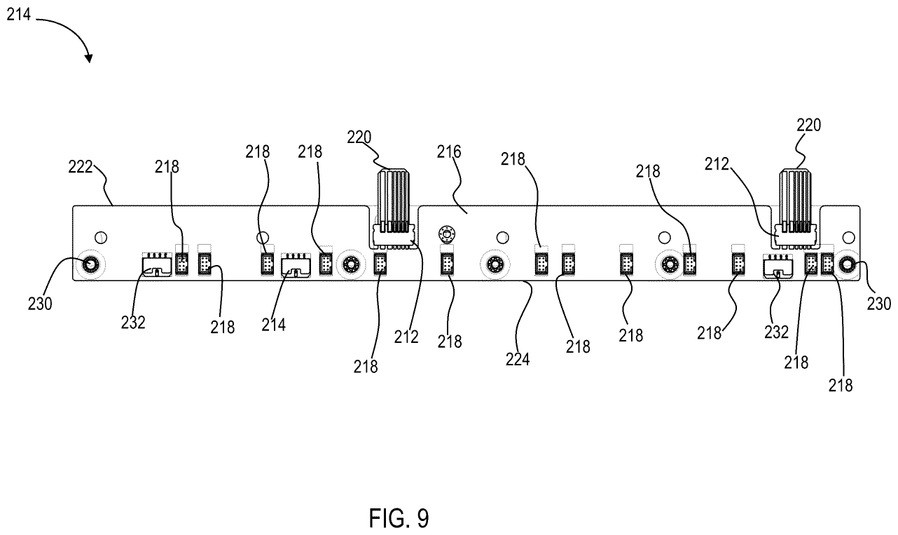

A receptacle 244 is a volume of space defined by (between) top wall 236, bottom wall 238, and side walls 240 and 242. Receptacle 244 has openings such that system board connector 212 is able to receive a connector, such as elongated edge connector 220. More specifically, in the illustrated example, receptacle 244 comprises an inlet opening 244a at a front end thereof and an outlet opening 244b at a rear end thereof, with the outlet opening 244b disposed opposite the inlet opening 244a. Thus, in use, an distal end of the elongated edge connector 220 may be inserted into the receptacle 244 of the system board connector 212 through the inlet opening 244a (see FIGS. 7 and 8), pass through the receptacle 244, and then ultimately pass out of the receptacle 244 through the outlet opening 244b (see FIG. 8). In this state, a distal end of the edge connector 220 is positioned rearward of the connector 212, a middle portion of the edge connector 220 is positioned within the receptacle 244, and a proximal end of the edge connector 220 is positioned forward of the connector 212, as shown in FIGS. 8 and 9. Furthermore, as shown in FIGS. 8 and 9, the edge connector 220 can be moved through the receptacle 244 by varying amounts such that a distance between the distal end of the edge connector 220 and the rear end of the system board connector 212 can vary. For example, FIG. 8 shows the edge connector 220 in a first position in which the distal end thereof is a distance d1 rearward of the rear end of the connector 212, and FIG. 9 shows the edge connector 220 in a second position in which the distal end thereof is a distance d2 rearward of the rear end of the connector 212. It should be understood that the edge connector 200 could also take any of the intermediate positions between the first and second position. Furthermore, the connector 220 does not necessarily have to alt pass fully through the receptacle 244. If desired, it is also possible for the edge connector 220 to be inserted only partway into the receptacle 244 such that the distal end of the elongated edge connector 220 may remain within the receptacle 244 and does not pass through the outlet opening 244b. As such, the system board connector 212 may allow for multiple installation positions of the elongated edge connector 220 relative to the system board connector 212. Because the system board connector 212 is fixed to a system board during usage, this variability in positioning of the edge connector relative to the system board connector 212 allows the fan board 214 to be installed in a variety of positions along the front/rear axis relative to the system board.

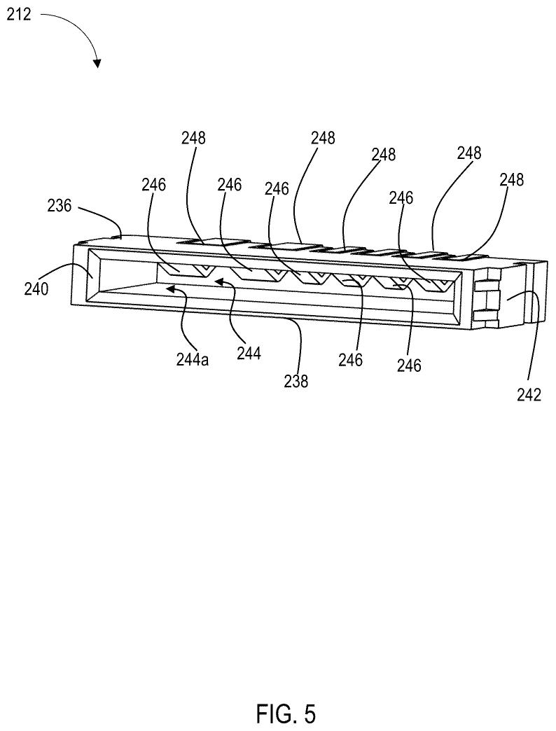

System board connector 212 may further include a plurality of electrical pins 246. As shown in FIGS. 4 and 5, electrical pins 246 may extend downwardly from an inner surface of the top wall 236 such that electrical pins 246 extend into receptacle 244. By extending into the receptacle 244, electrical pins 246 are able to contact an elongated edge connector 220 at the contact leads 221. More particularly, contact leads 221 may contact electrical pins 246 as elongated edge connector 220 slides through the receptacle 244. Electrical pins 246 may be manufactured of a flexible and conductive material, such as a thin sheet of copper, gold, or gold-plated copper, that is coupled to a system board connector 212.

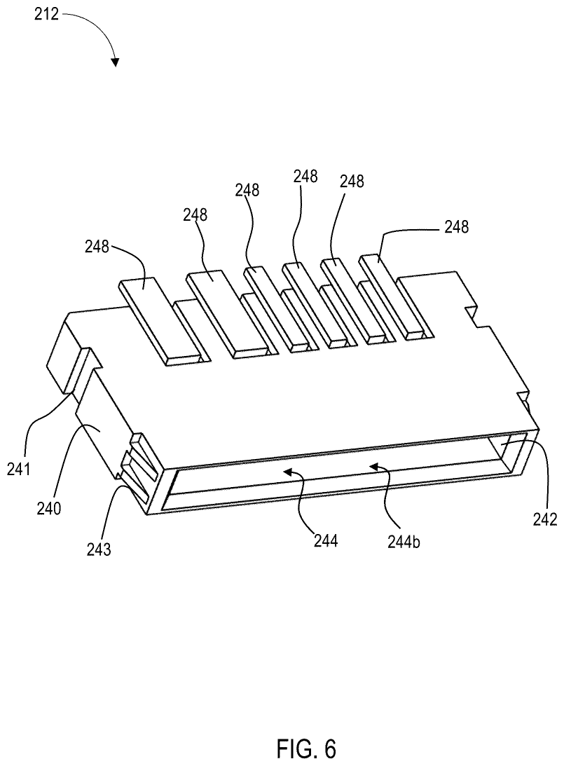

Corresponding electrical leads 248 may be disposed on an outer surface of the top wall 236, as shown particularly in FIGS. 5 and 6. Electrical leads 248 may similarly be made of conductive material, such as copper, gold, or gold-plated copper, and, when system board connector 212 is coupled to a system board (such as one of the system boards 308, 408, 508, 608, which are described below), electrical leads 248 provide electrical connection between the system board and the system board connector 212. Each electrical pin 246 extends through the top wall 236 and is electrically connected to one of the electrical leads 24.

When a connector, such as elongated edge connector 220, is inserted into the receptacle 244 of system board connector 212, the contact leads 221 contact the electrical pins 246. By sliding or otherwise moving the elongated edge connector 220 through the receptacle 244, contact is maintained between the contact leads 221 and electrical pins 246. Because the electrical pins 246 are flexible and thus are deformable, the force introduced by the elongated edge connector 220 urges the electrical pins 246 upwards, away from the center of the receptacle 244. This upward movement of the electrical pins 246 makes room for the edge connector 220 to pass through the receptacle 244. In addition, the deformation of the electrical pins 246 causes the pins 246 to generate restoring spring forces which push the pins 246 back against the contact leads 221 of the edge connector 220, thus maintaining firm contact between the electrical pins 246 and the contact leads 221 as long as the elongated edge connector 220 remains moving through or stationary in the system board connector 212. As previously noted, the pins 246 are electrically connected to the leads 248, which are in turn electrically connected to a system board, and thus when the pins 246 are in contact with the leads 221, electrically connective paths are formed between the leads 221 and the system board via pins 246 and leads 248. Thus, elongated edge connector 220 (and thus fan board 214) is able to receive power from the system board via the contact between the electrical leads 248 and the system board, the electrical leads 248 and the electrical pins 246, and the electrical pins 246 and the contact leads 221.

As discussed particularly with respect to FIGS. 2-3, the length of elongated edge connector 220 allows fan board 214 to move with respect to system board connector 212, and thus with respect to system board, such that fan board 214 may be positioned in a variety of positions with respect to the system board 208. This variable positioning is shown in particular in FIGS. 7-9. FIGS. 7-9 omit the system board to allow a clearer view of the interaction between the fan board 214 and the system board connector 212; however, it should be understood that system board connectors 212 are coupled to a system board.

A rear edge 222 of fan board 214, from which elongated edge connectors 220 protrude, faces system board connectors 212 to allow elongated edge connectors 220 to engage with system board connectors 212. Disposed opposite rear edge 222 is front edge 224. Fan receptacles 218, as well as power connectors 232, are disposed along a length of fan board 214 atop PCB 216 and adjacent to front edge 224. Fan board 214 includes openings 230 at which the fan board 214 could be coupled to a chassis via fasteners, also not shown in FIGS. 7-9.

As previously discussed with respect to FIGS. 2-3, elongated edge connectors 220 extend outwardly from PCB 216 from the displaced rear edge 222a of fan board 214. In the first installation state shown in FIG. 7, corresponding to an unconnected state of the elongated edge connectors 220 with corresponding system board connectors 212, elongated edge connectors 220 are not electrically coupled to the system board.

A second installation state, in which the elongated edge connectors 220 have been partially inserted through system board connectors 212, is shown in FIG. 8. In FIG. 8, the fan board 214, and in particular the elongated edge connectors 220, have made contact with system board connectors 212. As described with respect to FIGS. 4-6, elongated edge connectors 220 slidably engage with system board connectors 212 through the receptacle 244 defined therein. More particularly, as shown in FIG. 8, a distal portion of elongated edge connector 220 extends through system board connector 212. However, in the second installation state shown in FIG. 8, the full length of the elongated edge connector 220 has not passed through system board connector 212; that is system board connector 212 has not reached displaced rear edge 222a of fan board 212 and an additional portion of elongated edge connector 220 remains available to pass thorough system board connector 212.

FIG. 9 shows a third installation state with nearly the full length of the elongated edge connectors 220 having passed through the system board connectors 212 such that system board connectors 212 are adjacent to displaced rear edge 222a of fan board 214. As previously mentioned, the cutouts 234 bordering elongated edge connectors 220 are configured to receive the side walls 240 and 242 of the system connector 212, which allows the system connector 212 to be positioned forward of the rear edge portions 222b as shown in FIG. 9. In other words, the cutouts 234 allow elongated edge connectors 220 to be moved with substantially their full length being inserted into and/or passing through system board connectors 212 even though only part of the edge connectors 220 protrudes rearward of the rear edge portions 222b. As a result, the fan board 214 is able to move with respect to the system board connectors 212, and thus with respect to the system board, into a plurality of installation positions. While FIGS. 8 and 9 show two possible installation positions of the fan board 214, examples are not so limited and any location along the length of edge connectors 220 may be installation positions. In addition, as will be discussed further herein, the edge connectors 220 may, in some systems, have different installation positions with respect to the one other (i.e., the two edge connectors 220 do not necessarily have to be inserted the same distance into their respectively corresponding system board connectors 212). As discussed with respect to FIGS. 4-6, the system board connectors 212 include electrical pins 246 that contact the contact leads 221 of the elongated edge connectors 220 when an elongated edge connector 220 slides through receptacle 244 of a system board connector 212. Thus, provided that contact leads 221 are in contact with electrical pins 246 of system board connector 212, elongated edge connector 220, and thus fan board 214, can be positioned an infinite number of distances from the system board. In other words, the contact leads 221 and electrical pins 246 maintain contact continuously throughout the entirety of a range of movement of the edge connector 220 relative to the system board connector 212, and thus the available positions for the fan board 214 relative to the system board vary continuously (infinitely) within that range of movement (as opposed to having only certain finite, discrete, or discontinuous installation positions). In some examples, this range of movement of the edge connector 220 in which electrical contact is maintained with the system board connector 212 (i.e., the range of valid installation positions for the edge connector 220 relative to the system board connector 212) is equal to or greater than 20 mm, in other examples equal to or greater than 30 mm, and in other examples is equal to or greater than 40 mm.

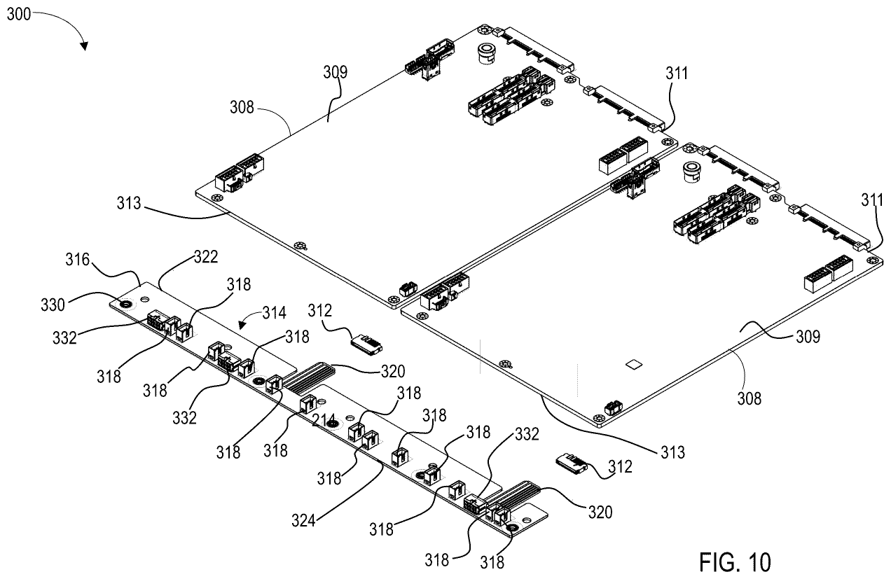

Turning to FIGS. 10-14, an example information processing system 300 including two system boards 308 and a fan board 214 will be described. Information processing system 300 may be one implementation of information processing system 100 shown in and described with respect to FIG. 1. FIGS. 10-14 do not show the chassis but it is to be understood that information processing system 300 may be disposed in a chassis such as chassis 102, shown in and described with respect to FIG. 1.

The system 300 utilizes an instance of the fan board 214 described above, as well as two instances of the system board connectors 212 described above. Each of the system board connectors 212 is connected to one of the system boards 308.

In this system 300, there are two system boards 308, which includes a first system board 308-1 and a second system board 308-2. Theses system boards 308 are disposed laterally adjacent to one another within the chassis.

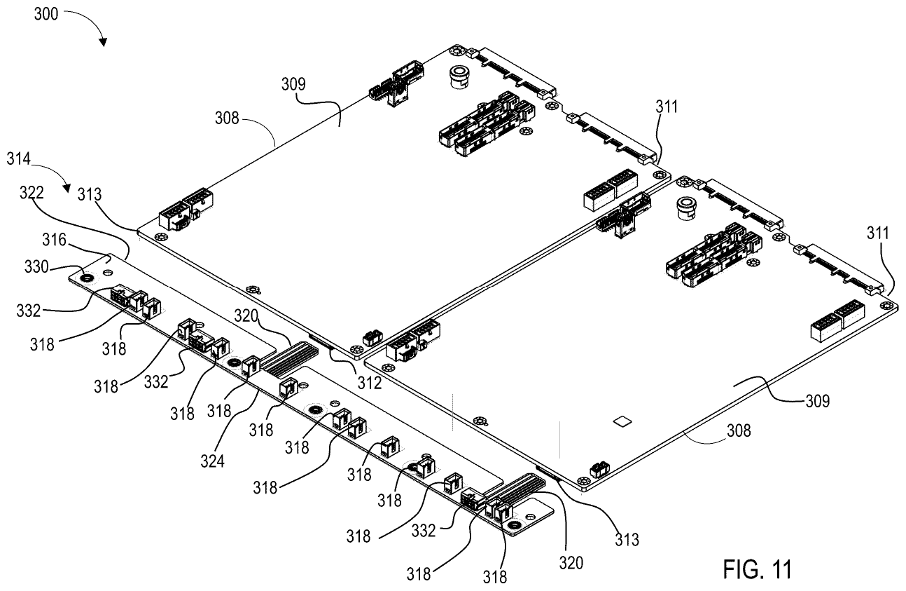

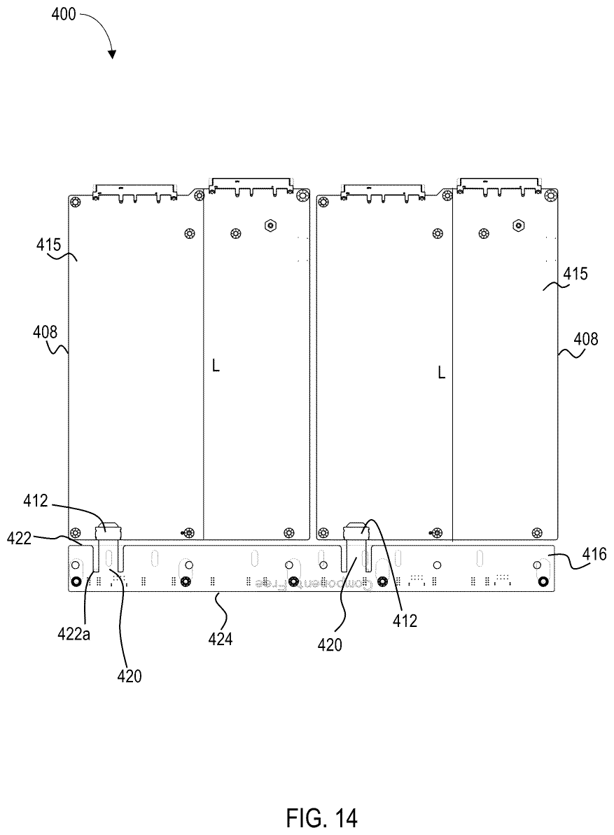

Each system board 308 may have a top surface 309 to which a processor, as well as other components (not shown in FIGS. 10-14) are mounted or coupled. Disposed opposite top surface 309 is a bottom surface 315, as shown in FIG. 14. As shown in FIGS. 11 and 14, system board connectors 212 are coupled to system boards 308 at the bottom surfaces 315 thereof. Specifically, a first system board connector 212-1 is connected to the bottom surface 315 of the first system board 308-1 and a second system board connector 212-2 is connected to the bottom surface 315 of the second system board 308-2. Electrical contacts (not visible) on the bottom surfaces 315 of the system boards 308 may be electrically connected (e.g., via solder) to the contacts 248 on the top sides of the connectors 212. These electrical contacts on the bottom of the system boards 308 are, in turn, electrically connected to electrical circuitry inside the system boards 308, and thus the system board connectors 212 are electrically connected to one or more of the electronic components of the system board 308.

System board 308 further has a rear edge 311 and a front edge 313 disposed opposite and parallel to rear edge 311. When installed in a chassis, front edge 313 faces a front panel of the chassis. As shown in FIG. 11, system board connectors are coupled to system board 308 adjacent to the front edge 313 of system board 308. In this example, both system boards 308 have similar form factors, most notably they have the same lengths in the front/rear dimension (i.e., the rear edge 311 and a front edge 313 are separated by the length L in both system boards 308).

FIG. 11 shows the system 300 in a first installation state of the fan board 214 in which the fan board 214 is not yet connected to the system boards 308. This first installation state is a preliminary state in the installation process, and the fan board 214 is not fully installed in this state. In this state, the fan board 214 is positioned forward of the system boards 308 with the elongated edge connectors 220 thereof aligned with the system board connectors 212 of the system boards 308—i.e., a first elongated edge connector 220-1 is aligned with first system board connector 212-1 and a second elongated edge connector 220-2 is aligned with second system board connector 212-2. As shown in FIG. 11, showing the system board connectors 212 coupled to the system board 308, rear edge 222 of PCB 216 of fan board 214 faces the front edge 313 of the system board 308. As a result, the elongated edge connectors 220 face the system board connectors 212 so that elongated edge connectors 220 can engage with the system board connectors 212, allowing fan board 214 to move with respect to system board 308.

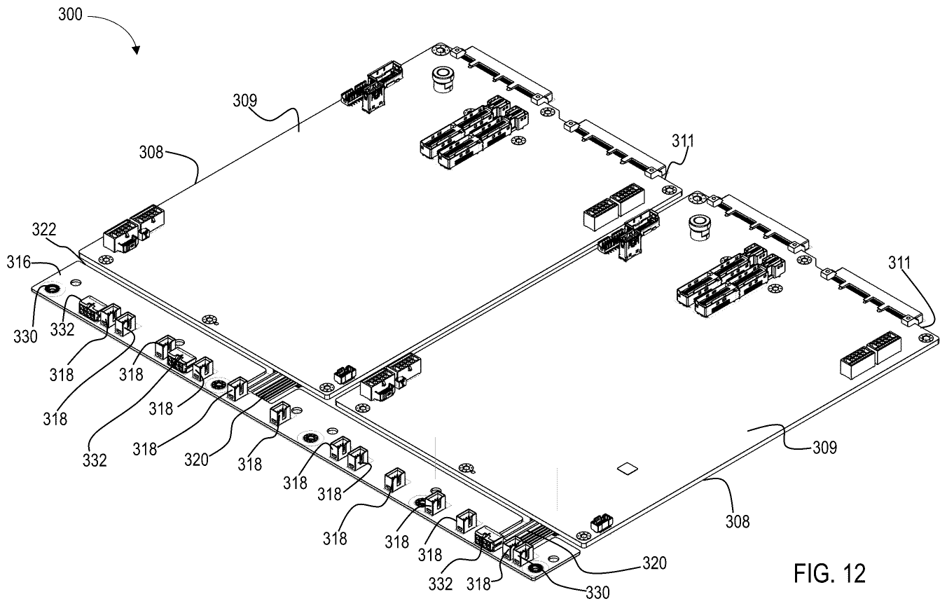

FIGS. 12-14 show the system 300 in a second installation state of the fan board 214 in which the fan board 214 is electrically connected to the system boards 308. In this state, the fan board 214 is in a first connection position, as is shown in FIG. 12, in which the elongated edge connectors 220 are engaged with the system board connectors 212. This first connection position corresponds to the position shown in FIG. 8. In this position, the distal ends of the edge connectors 220 pass below the system boards 308, as shown in FIG. 14. This second installation state is a fully installed state of the fan board 214, i.e., the fan board 214 is in an installed position with respect to the system board 308. In this first connection position, because elongated edge connectors 220 are engaged with the system board connectors 212, power is able to be provided to components mounted on PCB 216, such as fan receptacles 218 and power connectors 232. Thus, upon installation of fans, such as fans 126 described with respect to FIG. 1, into information processing system 300, the fan receptacles 218 are able to provide power due to their electrical connection with the elongated edge connectors 220.

As shown in FIG. 14, system board connectors 212 are coupled to the bottom surfaces 315 of system boards 308. A portion of elongated edge connectors 220 extend through the system board connectors 212 such that rear edge 222 of PCB 216 approaches the system boards 308.

The particular distance that elongated edge connectors 220 are extended through system board connectors 212 may vary from one implementation to the next depending on the dimensions of the system boards and the configuration of the chassis. Generally, the fan board 214 has a predetermined installation position in the chassis, which is set so as to enable the fans to appropriately connect with the fan connectors 218 of the fan board 214. Accordingly, because the fan board 214 is at a predetermined position in the chassis when installed, the location of the distal ends of the edge connectors 220 relative to the front edges of the system boards will be determined based on the positions of the front edges 313 within the chassis. In other words, the distance that the edge connectors 220 protrude beyond the front edges of the system boards 308 may vary depending on the lengths of the system boards which are used.. Said differently, the amount the fan board 214 is translated with respect to system board 208 during installation (i.e., in moving between the first installation state of FIG. 11 and the second installation state of FIG. 12) may depend on the length L of the system boards 308. As a result, fans may be coupled to the fan board 214 at the fan receptacles 218 to provide cooling for information processing system 300.

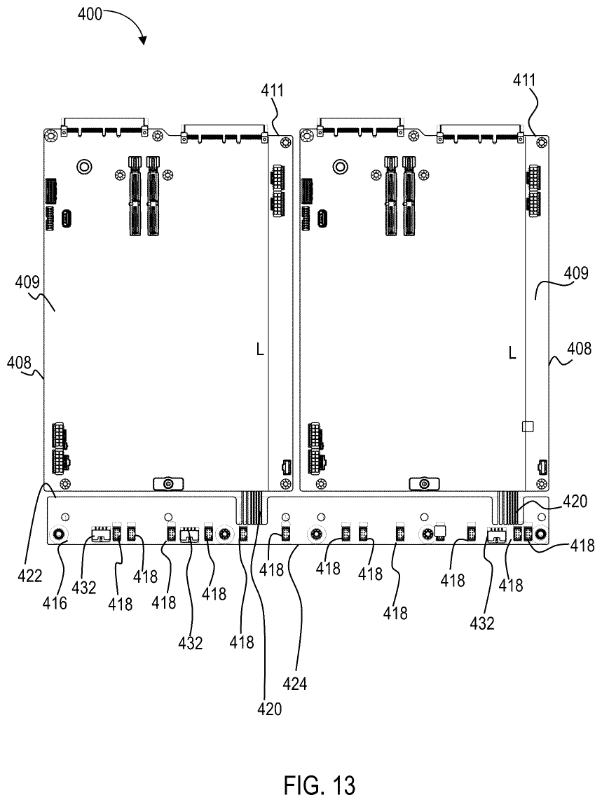

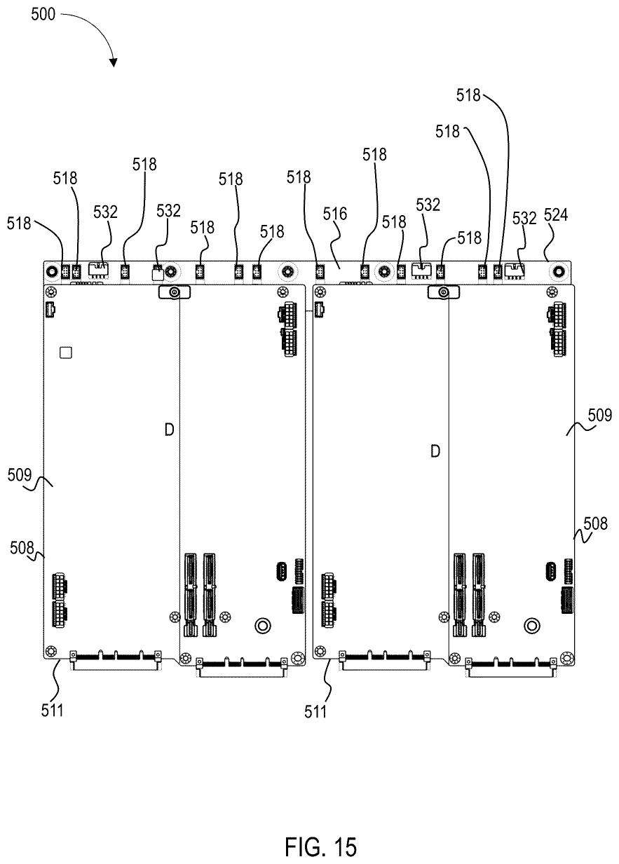

In the example of FIGS. 10-14, the front edge 313 of each system board 308 is located a distance d3 from a rear panel (not illustrated) of the system, as shown in FIG. 13. Moreover, in this example, in the fully instated state of the fan board 214, the front edge of the fan board 214 is located a distance d4 from the rear panel. Consequently, the distal edge of the elongated edge connectors 220 protrudes a distance d5 rearward of the front edge 313 of the system board 308. In contrast, in other examples shown in FIGS. 15-18 and described below, system boards having other lengths are used and consequently the distal edge of the edge connectors 220 may protrude other distances rearward of the front edge 313.

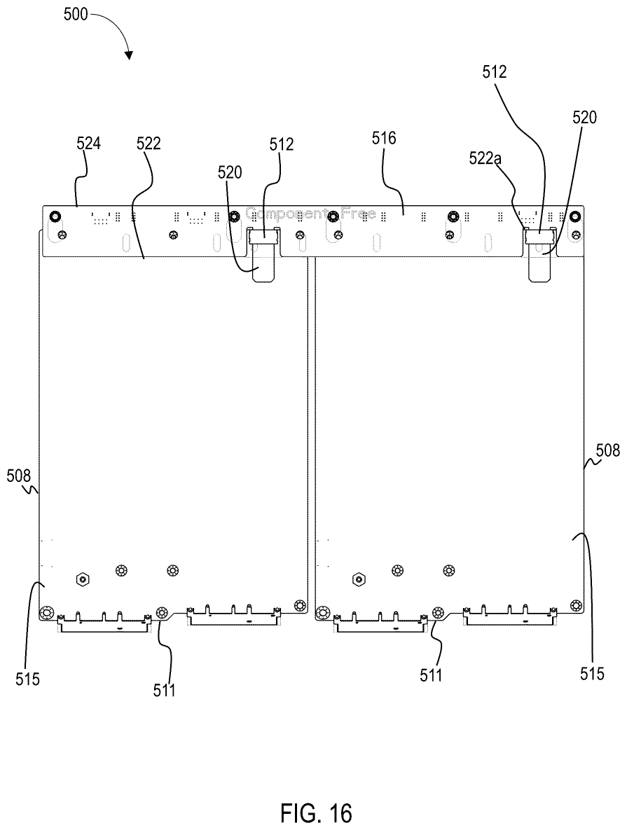

Another example information processing system 500 is shown in FIGS. 15-16. Like information processing system 300 shown and discussed with respect to FIGS. 10-14, information processing system 300 includes a pair of system boards, namely system boards 508-1 and 508-2. However, the system boards 508 are longer in the front/rear dimension than the system boards 308.

The system boards 508 have a top surface 509 and a bottom surface 515. Each system board 508 has a rear edge 511 and a front edge 513 disposed opposite rear edge 511, separated by a length D. Length D may be different from (longer than) length L, shown in FIGS. 13-15; however the same fan board 214 may be used in both systems 300 and 500, as well as the same system board connectors 212.

In the example of FIGS. 15 and 16, the front edges 513 of each system board 508 is located a distance d6 from a rear panel (not illustrated) of the system, where d6 is greater than d3. Thus, in the system 500 the front edges 513 of the system boards 508 are located farther forward in the system than the front edge 313 of the system boards 308 of the system 300. Moreover, in this example, in the fully instated state of the fan board 214, the front edge of the fan board 214 is located a distance d4 from the rear panel, which is the same location of the fan board 214 as in the system 300. Consequently, the distal edge of the elongated edge connectors 220 protrudes a distance d7 rearward of the front edge 513 of the system board 508, wherein d7 is greater than d5. In other words, as shown in FIG. 16, in this example, elongated edge connectors 220 are extended substantially fully through system board connectors 212, such that system board connectors 212 are adjacent to displaced rear edge 222a. Thus, because the system boards 508 of system 500 are longer than the system boards 308 of system 300, the elongated edge connectors 220 protrude farther beyond the front edges of the system boards in system 500 than in the system 300. Put another way, the ability of the elongated edge connectors 220 and the system board connectors 212 to have variable positions relative to one another allows for the same fan board 214 to be used in different systems 300/500 having differently sized system boards 308/508.

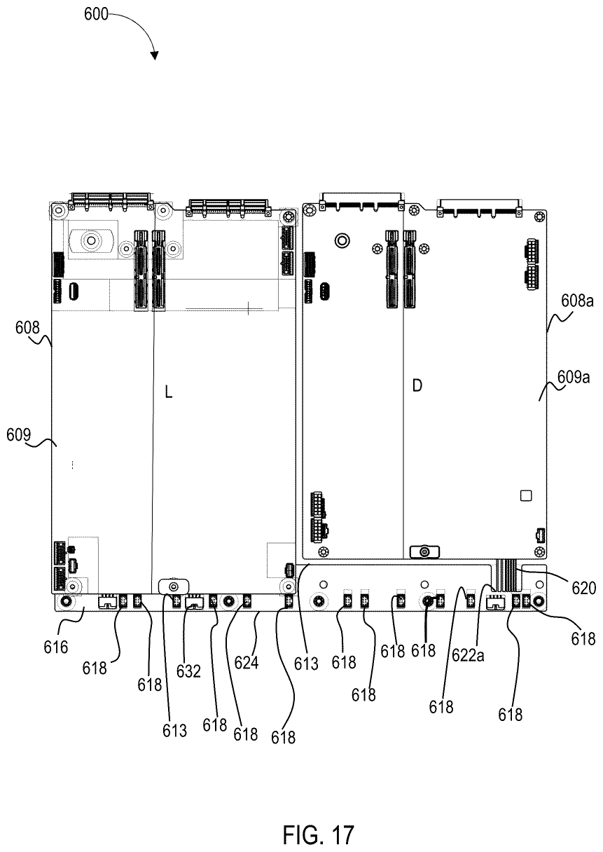

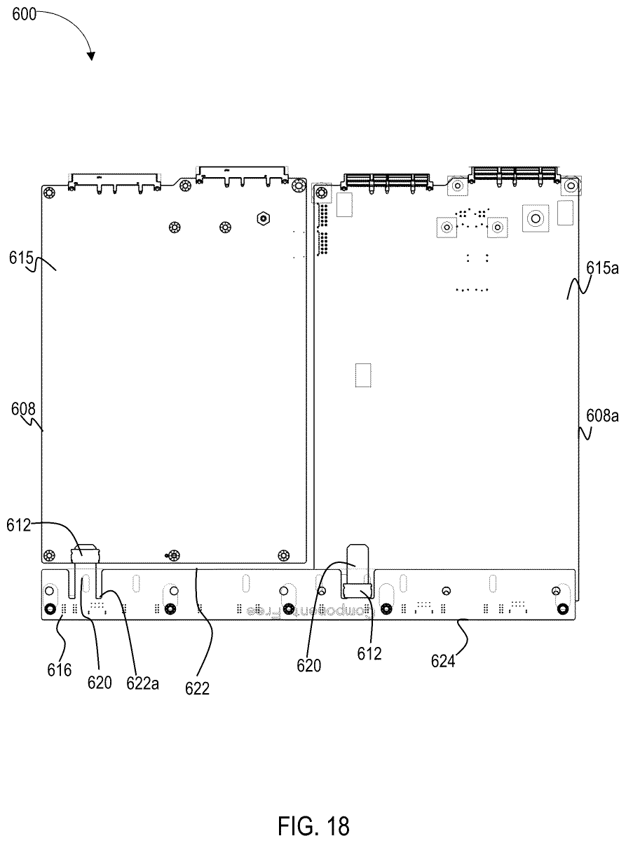

FIGS. 17-18 show a third example information processing system 600 having a first system board 608 and a second system board 608a. As shown in FIG. 17, first system board 608 has a length L and second system board 608a has a length D, with length D being shorter than length L. (In some examples, system board 608 may be the same as, or substantially similar to, the system board 508 while system board 608a may be the same as, or substantially similar to, the system board 308). However, despite these differences in form factor, a single fan board 214 is coupled to both first system board 608 and second system board 608a. Because elongated edge connectors 220 has an elongated shape with sufficient length (in some examples, a length of between thirty and forty millimeters), each elongated edge connector 220 is able to be coupled to a system board 608 or 608a, despite system board 608 having a different length than system board 608a. FIG. 18 in particular shows the connection between each elongated edge connector 220 and a respective system board connector 212. The elongated edge connector 220 engaged with the system board connector 212 coupled to the first system board 608 extends through the system board connector 212 a first distance, while the elongated edge connector 220 engaged with the system board connector 212 coupled to the second system board 608a extends through the system board connector 212 a second distance that is greater than the first distance. In this manner, a single fan board 214 may be used with system boards having different lengths and dimensions.

In the example of FIGS. 17 and 18, the front edge 613 of system board 608 is located the distance d6 from the rear panel (not illustrated) of the system, whereas the front edge 613a of the system board 608a is located a distance d3 from the rear panel, wherein d6>d3. Moreover, in this example, in the fully instated state of the fan board 214, the front edge of the fan board 214 is located a distance d4 from the rear panel, which is the same location of the fan board 214 as in the systems 300 and 500.

Consequently, as shown in FIG. 18, the distal edge of the elongated edge connector 220-1 protrudes a distance d5 rearward of the front edge 613a of the system board 608a, whereas the distal edge of the elongated edge connector 220-2 protrudes a distance d7 rearward of the front edge 613 of the system board 608. In other words, as shown in FIG. 18, in this example, the elongated edge connectors 220 extend different distances through their respectively corresponding system board connectors 212.

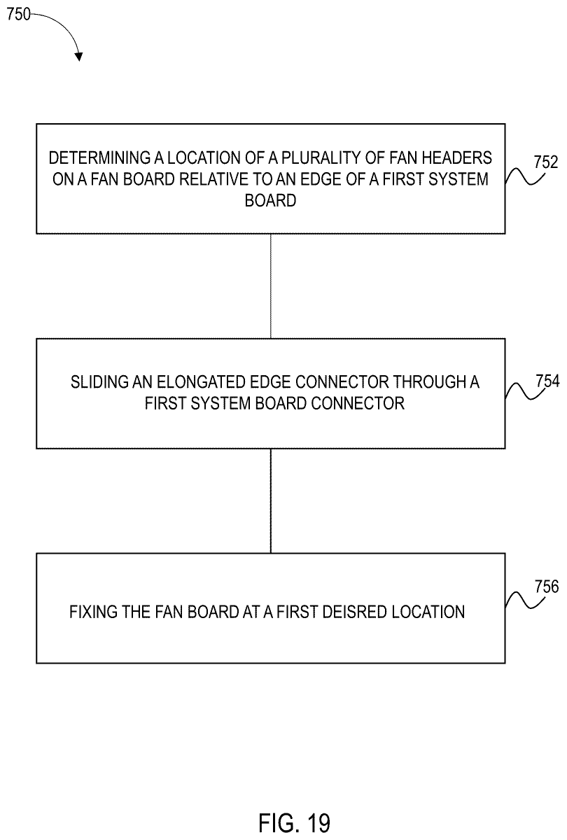

FIG. 19 is an example method 750 for installing a fan board with an elongated edge connector. At 752, method 750 includes determining a location of a plurality of fan receptacles on a fan board relative to an edge of a first system board. The location of the plurality of fan receptacles may be based on a length of a fan board, as well as a location of a front edge of the first system board. The location of the fan receptacles may be important due to allow fans to be coupled to the fan receptacles such that they are able to cool other components located on the system board.

At 754, method 750 includes sliding an elongated edge connector through a first system board connector. The elongated edge connector may be integrally formed on a PCB of a fan board, as shown and discussed with respect to FIGS. 2-3. The first system board connector may be akin to system board connector 212, discussed with respect to FIGS. 4-6. As described with respect to FIGS. 4-6, first system board connector may have a first receptacle that is defined by a top wall, a bottom wall, and a pair of side walls. The elongated edge connector may slidingly engage with the first system board connector; that is, the elongated edge connector may move through the first system board connector at the first receptacle. More particularly, the receptacle may have an inlet opening into which the elongated edge connector is inserted. The elongated edge connector is then moved through the receptacle such that a distal portion of the elongated edge connector extends through an outlet opening of the receptacle. The outlet opening may be disposed opposite the inlet opening.

As described with respect to FIGS. 4-6, the system board connector may include a plurality of electrical pins that extend into the system board receptacle. Thus, sliding an elongated edge connector through a first system board connector may include contacting the elongated edge connector with the plurality of electrical pins of the first system board connector. More particularly, contacting the elongated edge connector with the plurality of electrical pins may include maintaining contact between the elongated edge connector and the electrical pins as the elongated edge connector is slid or moved through the system board connector. In this manner, the elongated edge connector maintains electrical connection with the first system board.

At 756, method 750 includes fixing the fan board at a first desired location. The first desired location may be based on the location of the plurality of fan receptacles relative to the edge of the first system board. Said differently, the fan board may be fixed based on the determination made at 752. The fan board may be fixed when the elongated edge connector is moved a particular distance with respect to the first system board and the first system board connector.

Method 750 may further include determining the location of the plurality of fan receptacles on the fan board relative to an edge of a second system board. The second system board may have a length that is different from a length of the first system board, such that the location of the plurality of fan receptacles relative to the edge of the second system board is also different from the first determined location. Upon the determination of the location of the fan receptacles relative to the edge of the second system board, method 750 may include sliding the elongated edge connector through a second system board connector mounted to the second system board. As with the first system board connector, the second system board connector may include a second receptacle defined by a top wall, bottom wall, and side walls of the second system board connector. The elongated edge connector may slide with respect to the second system board connector via movement through the second receptacle.

Method 750 may include fixing the fan board a second desired location. The second desired location may be based on the determined location of the plurality of fan receptacles relative to the edge of the second system board. The determined location of the plurality of fan receptacles relative to the edge of the second system board is different than the determined location of the plurality of fan receptacles relative to the edge of the first system board and thus, the second desired location may be different than the first desired location. In this way, the fan board may be fixed at more than one desired location, with the desired location depending on a particular system board and the location of the fan receptacles relative to the particular system board.

It is to be understood that both the general description and the detailed description provide example implementations that are explanatory in nature and are intended to provide an understanding of the present disclosure without limiting the scope of the present disclosure. Other examples in accordance with the present disclosure will be apparent to those skilled in the art based on consideration of the disclosure herein. For example, various mechanical, compositional, structural, electronic, and operational changes may be made to the disclosed examples without departing from the scope of this disclosure, including for example the addition, removal, alteration, substitution, or rearrangement of elements of the disclosed examples, as would be apparent to one skilled in the art in consideration of the present disclosure. Moreover, it will be apparent to those skilled in the art that certain features or aspects of the present teachings may be utilized independently (even if they are disclosed together in some examples) or may be utilized together (even if disclosed in separate examples), whenever practical. In some instances, well-known circuits, structures, and techniques have not been shown or described in detail in order not to obscure the examples. Thus, the following claims are intended to be given their fullest breadth, including equivalents, under the applicable law, without being limited to the examples disclosed herein.

References herein to examples, implementations, or other similar references should be understood as referring to prophetic or hypothetical examples, rather than to devices/systems that have been actually produced, unless explicitly indicated otherwise. Similarly, references to qualities or characteristics of examples should be understood as representing the educated estimates or expectations of the inventors based on their understanding of the relevant principles involved, application of theory and/or modeling, and/or past experiences, rather than as being representations of the actual qualities or characteristics of an actually produced device/system or the empirical results of tests actually carried out, unless explicitly indicated otherwise.

Further, spatial, positional, and relational terminology used herein is chosen to aid the reader in understanding examples of the invention but is not intended to limit the invention to a particular reference frame, orientation, or positional relationship. For example, spatial, positional, and relational terms such as “up”, “down”, “lateral”, “beneath”, “below”, “lower”, “above”, “upper”, “proximal”, “distal”, and the like may be used herein to describe directions or to describe one element's or feature's spatial relationship to another element or feature as illustrated in the figures. These spatial terms are used relative to reference frames in the figures and are not limited to a particular reference frame in the real world. Furthermore, if a different reference frame is considered than the one illustrated in the figures, then the spatial terms used herein may need to be interpreted differently in that different reference frame. Moreover, the poses of items illustrated in the figure are chosen for convenience of illustration and description, but in an implementation in practice the items may be posed differently.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as coupled may be electronically or mechanically directly coupled, or they may be indirectly coupled via one or more intermediate components, unless specifically noted otherwise.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition. Moreover, unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within ±1% of the stated value, property, or relationship unless indicated otherwise.

What is claimed is:

1. A system, comprising:
a chassis;
a system board supported by the chassis and having a processor mounted thereto;
a system board connector coupled to the system board;
a fan board supported by the chassis and comprising:
a printed circuit board (PCB);
a plurality of fan receptacles mounted to the PCB and configured to mate with fan connectors of a plurality of fans; and
an elongated edge connector integrally formed with the PCB and electrically connected to the plurality of fan and configured such that the elongated edge connector is slidably engageable with the system board connector such that the fan board is movable relative to the system board between a plurality of installation positions, wherein:
a distance between a first point on the fan board and a second point on the system board varies between the plurality of installation positions; and
the elongated edge connector is electrically connected to the system board connector at each installation position of the plurality of installation positions.

2. The system of claim 1, wherein the system board further comprises:
a top surface to which the processor is mounted; and
a bottom surface to which the system board connector is mounted.

3. The system of claim 1, wherein:
the PCB of the fan board comprises a front edge facing a front panel of the chassis;
the system board comprises a front edge facing the front edge of the chassis;
the elongated edge connector is formed in a rear edge of the PCB of the fan board opposite the front edge of the PCB; and
the system board connector is mounted to the system board adjacent to the front edge of the system board.

4. The system of claim 3, wherein the rear edge of the PCB of the fan board comprises a first rear edge portion extending parallel to the front edge of the system board and the elongated edge connector protrudes rearward beyond the first rear edge portion.

5. The system of claim 1, wherein the system board connector further comprises:
an upper wall;
a lower wall;
a pair of side wall extending between and connecting the upper wall and the lower wall;
a receptacle defined by the upper wall, the lower wall, and the pair of side walls, the receptacle being configured to receive the elongated edge connector therein and to allow sliding engagement therewith; and
a plurality of electrical pins arranged in the receptacle to make sliding contact with corresponding electrical contacts of the elongated edge connector to electrically connect to elongated edge connector to the system board.

6. The system of claim 5, wherein:
the receptacle of the system board connector comprises an inlet opening and an outlet opening opposite the inlet opening;
the elongated edge connector is inserted into the receptacle via the inlet opening; and
the outlet opening is configured to allow a distal end of the elongated edge connector to pass out of the receptacle.

7. The system of claim 1, wherein:
the elongated edge connector has a length and a width; and
the length is greater than the width such that the elongated edge connector is columnar in shape.

8. The system of claim 1, wherein:
the PCB of the fan board further comprises:
a rear edge comprising a first rear edge portion and a second rear edge portion which is offset forward of the first rear edge portion; and
a pair of cutouts extending from the first rear edge portion forward to the second rear edge portion;
the elongated edge connector is coupled to the fan board at the second rear edge portion such that the elongated edge connector protrudes rearward from the second rear edge portion and is bordered along the sides by the pair of cutouts.

9. A system, comprising:
a system board having a top face, a bottom face, and a processor mounted to the top face;
a system board connector mounted to the bottom face of the system board, wherein:
the system board connector further comprises a top portion, a bottom portion, and a pair of side walls disposed between and connecting the top portion and the bottom portion; and
the top portion, bottom portion, and side walls define a receptacle, wherein the receptacle comprises an inlet opening at a first end of the system board connector and an outlet opening at a second end of the system board connector;
a fan board coupled to the system board, wherein the fan board comprises:
a printed circuit board (PCB) comprising a cutout at a rear edge thereof;
a plurality of fan receptacles mounted to the PCB and configured to mate with fan connectors of a plurality of fans; and
an elongated edge connector integrally formed with the PCB and joined to a remainder of the PCB in the cutout, wherein:
the elongated edge connector extends from an end of the cutout towards the system board; and
the elongated edge connector is slidably engageable with the system board connector through the receptacle such that the fan board is movable with respect to the system board.

10. The system of claim 9, wherein the system board connector further comprises a plurality of electrical pins arranged in the receptacle to contact corresponding electrical contacts of the elongated edge connector as the elongated edge connector moves with respect to the receptacle such that the elongated edge connector is electrically connected to the system board.

11. The system of claim 9, wherein the elongated edge connector is columnar in shape.

12. The system of claim 11, wherein the elongated edge connector has a length of between about 20 millimeters and about 40 millimeters and a width of between about 1 millimeter and 10 millimeters.

13. The system of claim 9, wherein the cutout of the PCB of the fan board is dimensioned such that the system board connector can slidably engage with a full length of the elongated edge connector.

14. The system of claim 9, wherein the fan board is movable between a plurality of positions with respect to the system board.

15. The system of claim 14, wherein the fan board is movable with respect to the system board by a distance of up to about 30 millimeters.

16. A method of installing a fan board in a computing system, comprising:
determining a location of a plurality of fan receptacles on a fan board relative to an edge of a first system board;
sliding an elongated edge connector integrally formed on a PCB of the fan board through a first system board connector mounted to the first system board, wherein the elongated edge connector moves through the first system board connector through a first receptacle defined by a top wall, a bottom wall, and a pair of side walls of the system board connector; and
fixing the fan board at a first desired location, wherein:
the first desired location is based on the location of the plurality of fan receptacles relative to the edge of the first system board; and
the fan board is fixed when the elongated edge connector is moved a first particular distance with respect to the first system board and the first system board connector.

17. The method of claim 16, further comprising:
determining the location of the plurality of fan receptacles on the fan board relative to an edge of a second system board, wherein the second system board has a length that is different from a length of the first system board;
sliding the elongated edge connector through a second system board connector mounted to the second system board, wherein the elongated edge connector moves through the second system board connector through a second receptacle; and
fixing the fan board at a second desired location, wherein:
the second desired location is based on the location of the plurality of fan receptacles relative to the edge of the second system board; and
the second desired location is different than the first desired location.

18. The method of claim 16, wherein sliding the elongated edge connector through the first system board connector further comprises:
inserting the elongated edge connector into an inlet opening of the receptacle of the first system board connector; and
moving the elongated edge connector through the receptacle such that a distal portion of the elongated edge connector extends through an outlet opening of the receptacle.

19. The method of claim 16, wherein sliding an elongated edge connector through a first system board connector further comprises contacting the elongated edge connector with a plurality of electrical pins of the first system board connector, wherein the plurality of electrical pins is disposed within the receptacle of the first system board connector.

20. The method of claim 19, wherein contacting the elongated edge connector with the plurality of electrical pins of the first system board connector maintains an electrical connection between the first system board and the elongated edge connector.
